(19) United States
(12) Patent Application Publication
(10) Pub. No.: US 2026/0155185 A1
(43) Pub. Date: Jun. 4, 2026

(54) FLASH MEMORY APPARATUS AND ERASING METHOD THEREOF

(71) Applicant: Winbond Electronics Corp., Taichung City (TW)

(72) Inventor: Chung-Zen Chen, HsinChu (TW)

(73) Assignee: Winbond Electronics Corp., Taichung City (TW)

(21) Appl. No.: 19/347,725

(22) Filed: Oct. 2, 2025

(30) Foreign Application Priority Data
Dec. 4, 2024 (TW) 113147068

(51) Int. Cl. G11C 16/16; G11C 16/34

(52) U.S. Cl. CPC G11C 16/16; G11C 16/3445

(57) ABSTRACT

A flash memory apparatus and an erasing method thereof are provided. The erasing method includes the following steps: applying an erase voltage to a target memory block among memory blocks; performing a first erase verification on the target memory block using a first erase verification voltage; performing a second erase verification on the target memory block using a second erase verification voltage higher than the first erase verification voltage in a case that a memory cell group failing the first erase verification is in the target memory block; and setting a first erase flag and a second erase flag corresponding to each memory cell group in the target memory block according to verification results of the first erase verification and the second erase verification to classify each memory cell group and accordingly adjust increase amount of the erase voltage.

### CROSS-REFERENCE TO RELATED APPLICATION

This application claims the priority benefit of Taiwan application serial no. 113147068, filed on December 4, 2024. The entirety of the above-mentioned patent application is hereby incorporated by reference herein and made a part of this specification.

### BACKGROUND

### Technical Field

The disclosure relates to a memory apparatus, and in particular relates to a flash memory apparatus and an erasing method thereof.

### Description of Related Art

Flash memory apparatuses may perform write operations, erase operations, and read operations, with the erase operation taking the longest time. Therefore, the duration required for the erase operation may be said to predominantly determine the performance of flash memory apparatuses. If an erase verification fails after applying the erase voltage multiple times, the erase voltage is increased to reduce the time required for the erase operation. However, the erase speed of each memory cell in a memory block is different. Even if only one memory cell in a memory block fails the erase verification, the erase voltage will still be applied to the entire memory block, which will not only increase the erase time but also increase the leakage current.

### SUMMARY

A flash memory apparatus and an erasing method thereof, which may dynamically adjust the increase amount of erase voltage and the range of applying the erase voltage, so as to improve the overall efficiency of the erase operation, are provided in the disclosure.

The erasing method of the disclosure is suitable for a flash memory apparatus including multiple memory blocks. Each of the memory blocks are divided into multiple memory cell groups. The erasing method of the flash memory apparatus includes the following operation. An erase voltage is applied to a target memory block among memory blocks. A first erase verification is performed on the target memory block using a first erase verification voltage. A second erase verification is performed on the target memory block using a second erase verification voltage higher than the first erase verification voltage in a case that a memory cell group failing the first erase verification is in the target memory block. A first erase flag and a second erase flag are set corresponding to each of the memory cell groups in the target memory block according to verification results of the first erase verification and the second erase verification to classify each of the memory cell groups and accordingly adjust increase amount of the erase voltage.

The flash memory apparatus of the disclosure includes a memory array, a flag register, and a control circuit. The memory array has multiple memory blocks, and each of the memory blocks are divided into multiple memory cell groups. The flag register is configured to store the first erase flag and the second erase flag corresponding to each of the memory cell groups. The control circuit is coupled to the memory array and the flag register, and is configured to perform an erase operation on a target memory block among the memory blocks. The control circuit applies an erase voltage to the target memory block, and performs a first erase verification on the target memory block using a first erase verification voltage. The control circuit uses a second erase verification voltage higher than the first erase verification voltage to perform a second erase verification on the target memory block in a case that a memory cell group failing the first erase verification is in the target memory block. The control circuit sets a first erase flag and a second erase flag corresponding to each of the memory cell groups in the target memory block according to verification results of the first erase verification and the second erase verification to classify each of the memory cell groups and accordingly adjust increase amount of the erase voltage.

Based on the above, the flash memory apparatus and the erasing method of the disclosure may dynamically adjust the increase amount of the erase voltage and the range of applying the erase voltage according to the type of the memory cell group that has not yet passed the erase verification. In this way, not only may the erase time spent in the erase operation be reduced, but an increase in leakage current may also be avoided, thereby improving the overall efficiency of the erase operation.

In order to make the above-mentioned features and advantages of the disclosure comprehensible, embodiments accompanied with drawings are described in detail below.

### BRIEF DESCRIPTION OF THE DRAWINGS

FIG. 1 is a schematic diagram of a flash memory apparatus according to an embodiment of the disclosure.

FIGS. 2A and FIG. 2B are flowcharts of the steps of an erasing method of a flash memory apparatus according to an embodiment of the disclosure.

FIGS. 3A and FIG. 3B are flowcharts of the steps of an erasing method of a flash memory apparatus according to an embodiment of the disclosure.

FIGS. 4A to FIG. 4C are flowcharts of the steps of an erasing method of a flash memory apparatus according to an embodiment of the disclosure.

### DETAILED DESCRIPTION OF DISCLOSED EMBODIMENTS

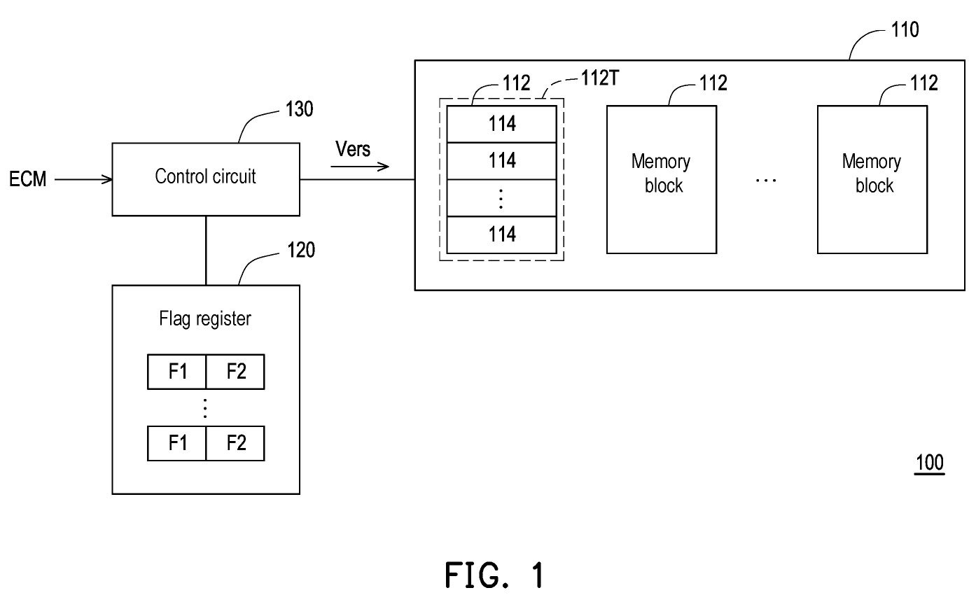

Referring to FIG. 1, a flash memory apparatus 100 of an embodiment of the disclosure is, for example, a NOR type and includes a memory array 110, a flag register 120, and a control circuit 130. The memory array 110 has multiple memory blocks 112. Each memory block 112 may be divided into multiple memory cell groups 114. Each memory cell group 114 includes multiple memory cells, such as a memory tunnel oxide (ETOX) structure. Each memory block 112 includes, for example, 16 sectors (i.e., 64K bytes) of memory cells. However, the disclosure does not limit the number of memory blocks 112, memory cell groups 114, and memory cells.

The flag register 120 is configured to store the erase flag F1 and the erase flag F2 corresponding to each memory cell group 114. The initial value of the erase flag F1 and the erase flag F2 corresponding to each memory cell group 114 is a second logical value (e.g., logic 0). In addition, although the flag register 120 is shown as being independent of the memory array 110 and the control circuit 130 in FIG. 1, the flag register 120 may also be integrated into the memory array 110 or the control circuit 130.

The control circuit 130 is coupled to the memory array 110 and the flag register 120. The control circuit 130 may select the target memory block 112T from the memory blocks 112 in the memory array 110 according to the received erase command ECM to perform an erase operation on the target memory block 112T. The control circuit 130 is, for example, a state machine, a central processing unit, or other programmable general-purpose or special-purpose microprocessor, a digital signal processor, a programmable controller, an application specific integrated circuit, a programmable logic device, or other similar devices or a combination of the devices thereof. It may also be a hardware circuit designed through a hardware description language or any other conventional digital circuit design method and realized through methods such as the field programmable logic gate array or complex programmable logic device.

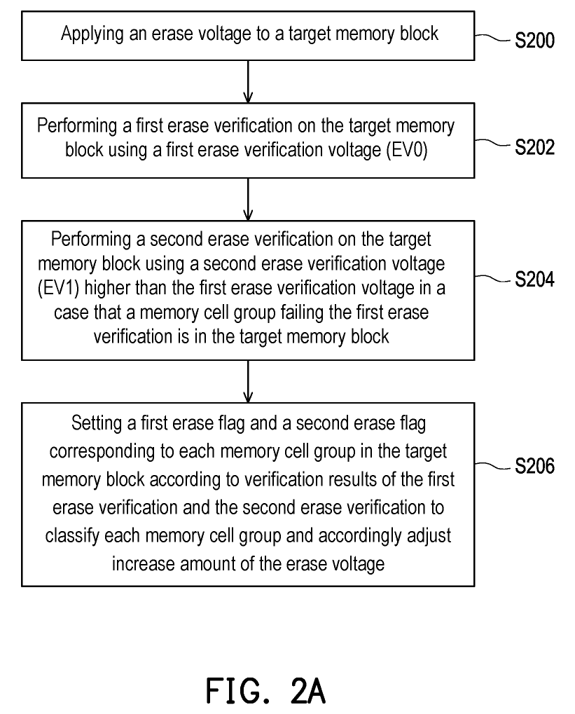

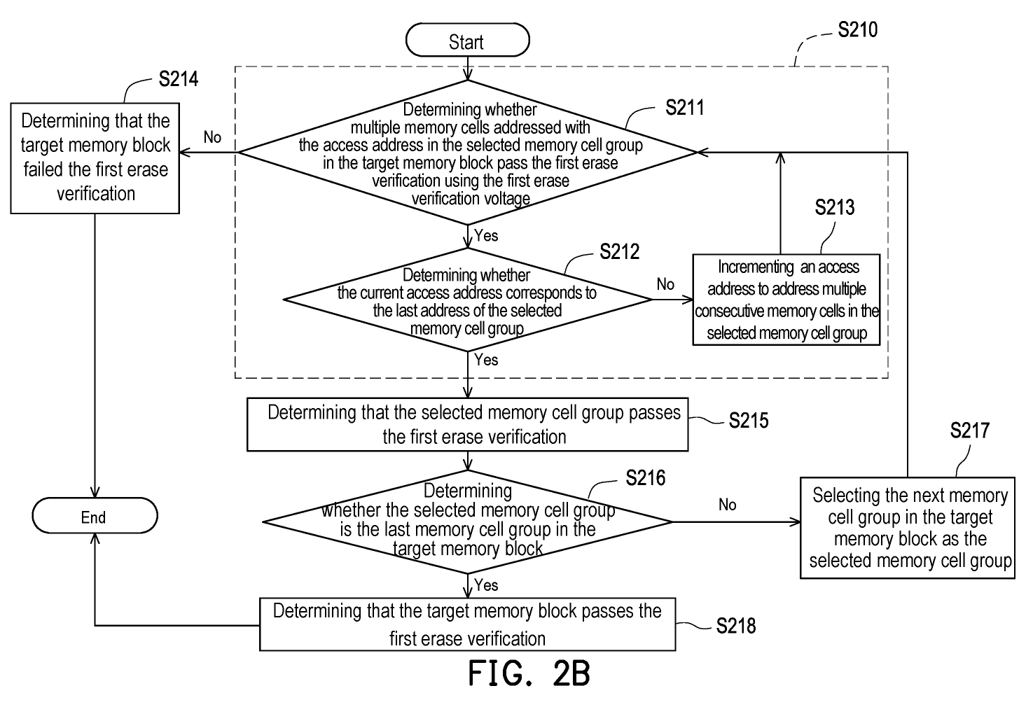

Referring to FIGS. 1 and FIG. 2A at the same time, the erasing method of this embodiment is applicable to the flash memory apparatus 100 in FIG. 1. Various steps of the erasing method according to the embodiment of the disclosure are described below with various elements in the flash memory apparatus 100. First, in step S200, the control circuit 130 applies the erase voltage Vers to the target memory block 112T. The initial value of the erase voltage Vers is, for example, about 15 volts.

Next, in step S202, the control circuit 130 performs a first erase verification on the target memory block 112T using the first erase verification voltage EV0. The first erase verification voltage is EV0. Specifically, due to the limited number of sensing amplifiers, the control circuit 130 may only obtain the threshold voltages of multiple memory cells (e.g., 16-byte memory cells) addressed by the access address in a selected memory cell group (one of the memory cell groups 114) among the target memory block 112T at a time, and compare the threshold voltages with the first erase verification voltage EV0. If the threshold voltage is less than the first erase verification voltage EV0, it means that the corresponding memory cell has passed the first erase verification (erase success). If the threshold voltage is not less than the first erase verification voltage EV0, it means that the corresponding memory cell has failed the first erase verification (erase failure).

Furthermore, for detailed steps of performing the first erase verification on the target memory block 112T using the first erase verification voltage EV0, reference may be made to each step in FIG. 2B. First, in step S210, the control circuit 130 determines whether the selected memory cell group in the target memory block 112T passes the first erase verification using the first erase verification voltage EV0. As shown in FIG. 2B, step S210 includes steps S211, S212 and S213. In step S211, the control circuit 130 determines whether multiple memory cells addressed with the access address in the selected memory cell group in the target memory block 112T pass the first erase verification using the first erase verification voltage EV0. When the addressed memory cell fails the first erase verification, in step S214, the control circuit 130 determines that the target memory block 112T failed the first erase verification. Incidentally, when performing an erase operation on the target memory block 112T, the selected memory cell group is initially, for example, the first memory cell group 114 in the target memory block 112T, and the initial value of the access address corresponds to, for example, the initial address of the first memory cell group 114.

When the addressed memory cell passes the first erase verification, in step S212, the control circuit 130 determines whether the current access address corresponds to the last address of the selected memory cell group. If not, in step S213, the control circuit 130 increments the access address to address multiple consecutive memory cells in the selected memory cell group, and returns to step S211 to continue the first erase verification.

If the current access address corresponds to the last address of the selected memory cell group, then in step S215, the control circuit 130 determines that the selected memory cell group passes the first erase verification. Next, in step S216, the control circuit 130 determines whether the selected memory cell group is the last memory cell group 114 in the target memory block 112T. If not, in step S217, the control circuit 130 selects the next memory cell group 114 in the target memory block 112T as the selected memory cell group, and returns to step S211 to continue the first erase verification.

If the selected memory cell group is the last memory cell group 114 in the target memory block 112T, then in step S218, the control circuit 130 determines that the target memory block 112T passes the first erase verification.

It should be noted that in this embodiment, each time the first erase verification is performed on the target memory block 112T, the first erase verification is performed on multiple memory cells addressed by the current access address. Since the access address will be incremented when the addressed memory cell passes the first erase verification, the first erase verification will not be repeated for the memory cells that have passed the first erase verification.

Returning to FIG. 2A, in step S204, in the case that a memory cell group 114 failing the first erase verification is in the target memory block 112T (i.e., the target memory block 112T failed the first erase verification), the control circuit 130 performs the second erase verification on the target memory block 112T using the second erase verification voltage EV1 which is higher than the first erase verification voltage EV0. The second erase verification voltage EV1 is, for example, higher than the first erase verification voltage EV0 by 0.5 to 1 volt.

Finally, in S206, the control circuit 130 sets the erase flag F1 and the erase flag F2 corresponding to each memory cell group 114 in the target memory block 112T according to the verification results of the first erase verification and the second erase verification to classify each memory cell group 114, and accordingly adjusts the increase amount of the erase voltage Vers.

Specifically, the control circuit 130 may set the erase flag F1 corresponding to each memory cell group 114 that passes the second erase verification to a first logical value (e.g., logic 1), and set the erase flag F2 corresponding to each memory cell group 114 that failed the second erase verification to a first logical value. Furthermore, the control circuit 130 may classify the memory cell group 114 in which the erase flag F1 is set to the first logical value (the memory cell group 114 without slow erase cells) as a normal group with a normal erase speed, and classify the memory cell group 114 in which the erase flag F2 is set to the first logical value (the memory cell group 114 with slow erase memory cells) as a slow group with a slow erase speed. Through the above method, the control circuit 130 may increase the increase amount of the erase voltage Vers for the memory cell group 114 classified as the slow group, thereby reducing the erase time required for the slow group and improving the overall efficiency of the erase operation.

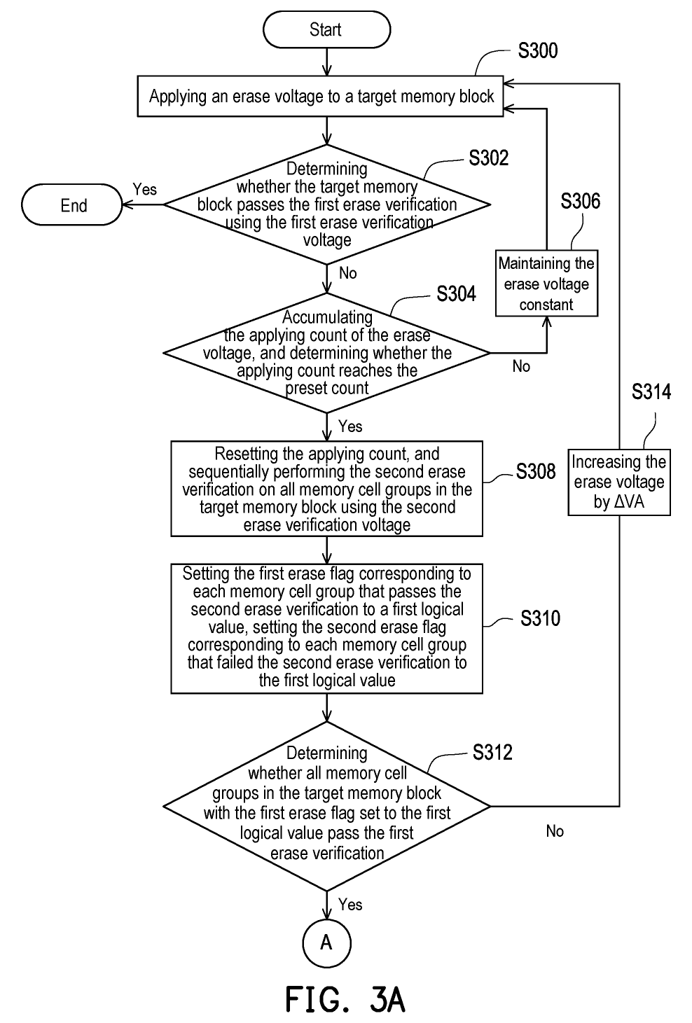

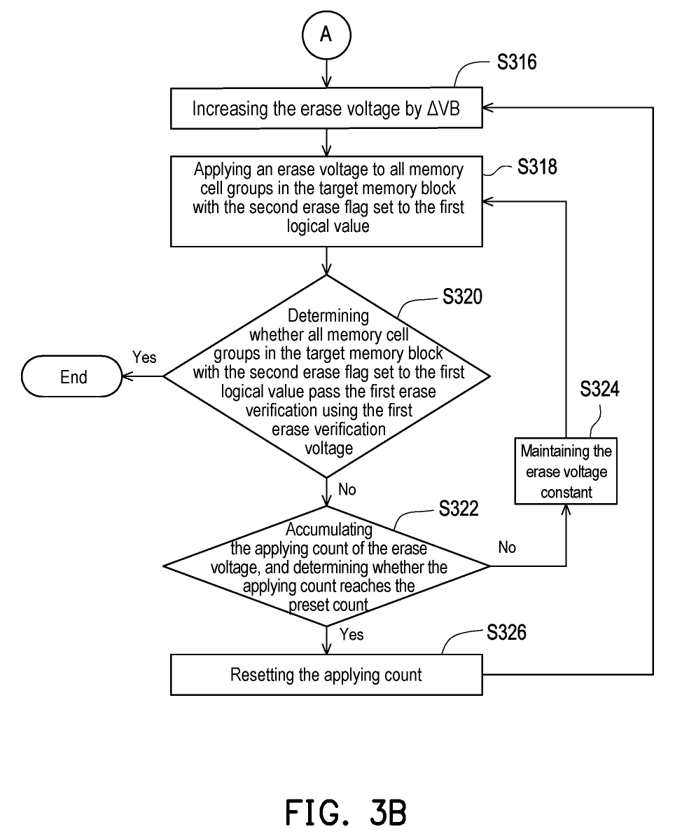

The erasing method of the disclosure will be described in more detail below with reference to the embodiment shown in FIGS. 3A and FIG. 3B. Referring to FIG. 1, FIGS. 3A and FIG. 3B at the same time, various steps of the erasing method according to the embodiment of the disclosure are described below with various elements in the flash memory apparatus 100. In this embodiment, the same or similar parts as those in the previous embodiment are not repeated herein. First, in step S300, the control circuit 130 applies the erase voltage Vers to the target memory block 112T. Next, in step S302, the control circuit 130 determines whether the target memory block 112T passes the first erase verification using the first erase verification voltage EV0. Specifically, the control circuit 130 may determine whether the memory cells addressed by the current access address in the target memory block 112T pass the first erase verification. If the memory cells addressed by the current access address pass the first erase verification, the control circuit 130 continues to increment the access address to repeatedly perform the first erase verification on the consecutive memory cells. When the control circuit 130 determines in step S302 that the last memory cell group 114 in the target memory block 112T also passes the first erase verification, it means that the target memory block 112T passes the first erase verification. At this time, the control circuit 130 will end the erasing method of this embodiment.

If the memory cells addressed by the current access address failed the first erase verification in step S302, it means that a memory cell group 114 that failed the first erase verification is in the target memory block 112T (i.e., the target memory block 112T failed the first erase verification). At this time, in step S304, the control circuit 130 accumulates the applying count of the erase voltage Vers, and determines whether the accumulated applying count reaches a preset count (e.g., 8 or 16 times). If not, in step S306, the control circuit 130 maintains the erase voltage Vers constant, and then returns to step S300 to continue applying the erase voltage Vers to the target memory block 112T. Thereby, the control circuit 130 may repeatedly apply the erase voltage Vers to the target memory block 112T until all memory cell groups 114 in the target memory block 112T pass the first erase verification.

Whenever the cumulative applying count of the erase voltage Vers reaches the preset count (Yes in step S304), in step S308, the control circuit 130 resets the applying count and sequentially performs the second erase verification on all memory cell groups 114 in the target memory block 112T using the second erase verification voltage EV1 to obtain all memory cell groups 114 in the current target memory block 112T that may pass the second erase verification.

Next, in step S310, the control circuit 130 sets the erase flag F1 corresponding to each memory cell group 114 that passes the second erase verification to a first logical value, and sets the erase flag F2 corresponding to each memory cell group 114 that failed the second erase verification to a first logical value.

Next, in step S312, the control circuit 130 determines whether all memory cell groups 114 in the target memory block 112T in which the erase flag F1 is set to the first logical value pass the first erase verification. If not, in step S314, the control circuit 130 increases the erase voltage Vers by the first increase amount ΔVA (e.g., 0.4 to 0.5 volts), and then returns to step S300 to continue applying the currently adjusted erase voltage Vers to the target memory block 112T.

If all memory cell groups 114 in the target memory block 112T in which the erase flag F1 is set to the first logical value pass the first erase verification, it means that all memory cell groups 114 classified as the normal group have passed the first erase verification, and only the memory cell groups 114 classified as the slow group have not passed the first erase verification. At this time, the process proceeds to step S316 of FIG. 3B via node A. In step S316, the control circuit 130 increases the erase voltage Vers by a second increase amount ΔVB (e.g., 0.8 to 1 volt) that is greater than the first increase amount ΔVA. Next, in step S318, the control circuit 130 only applies the erase voltage Vers to all memory cell groups 114 in the target memory block 112T in which the erase flag F2 is set to the first logical value (all memory cell groups 114 classified as the slow group).

Next, in step S320, the control circuit 130 determines whether all memory cell groups 114 in the target memory block 112T in which the erase flag F2 is set to the first logical value pass the first erase verification using the first erase verification voltage EV0. Specifically, the control circuit 130 may determine whether the memory cells addressed by the current access address in the target memory block 112T pass the first erase verification. If the memory cells addressed by the current access address pass the first erase verification, the control circuit 130 may continuously adjust the access address according to the addresses of all memory cell groups 114 in which the erase flag F2 is set to the first logical value (all memory cell groups 114 classified as the slow group), to repeatedly perform the first erase verification on multiple consecutive memory cells in all memory cell groups 114 classified as the slow group. When the control circuit 130 determines that the last memory cell group 114 of all memory cell groups 114 in which the erase flag F2 is set to the first logical value passes the first erase verification, it means that all memory cell groups 114 classified as the slow group have passed the first erase verification (Yes in step S320). At this time, the control circuit 130 will end the erasing method of this embodiment.

If the memory cells addressed by the current access address failed the first erase verification, it means that a memory cell group 114 that failed the first erase verification and the erase flag F2 set to the first logical value is still in the target memory block 112T (i.e. memory cell group 114 classified as the slow group) (No in step S320). At this time, in step S322, the control circuit 130 accumulates the applying count of the erase voltage Vers, and determines whether the accumulated applying count reaches a preset count. If not, in step S324, the control circuit 130 maintains the erase voltage Vers constant, and then returns to step S318 to continue applying the erase voltage Vers to all memory cell groups 114 in the target memory block 112T in which the erase flag F2 is set to the first logical value. Thereby, the control circuit 130 may repeatedly apply the erase voltage Vers to all memory cell groups 114 in the target memory block 112T in which the erase flag F2 is set to the first logical value (i.e., all memory cell groups 114 classified as the slow groups) until all memory cell groups 114 in the target memory block 112T in which the erase flag F2 is set to the first logical value pass the first erase verification.

Whenever the cumulative applying count of the erase voltage Vers reaches the preset count (Yes in step S322), in step S326, the control circuit 130 resets the applying count and returns to step S316 to increase the erase voltage Vers by the second increase amount ΔVB, and continues to apply the currently adjusted erase voltage Vers to the target memory block 112T in step S318.

Through the above method, the control circuit 130 may increase the increase amount of the erase voltage Vers after all memory cell groups 114 classified as the normal group have passed the first erase verification, and limit the range of applying the erase voltage Vers to the memory cell group 114 classified as the slow group. This not only reduces the erase time spent on the slow group, but also prevents the normal group from continuously generating leakage current, thereby improving the overall efficiency of the erase operation.

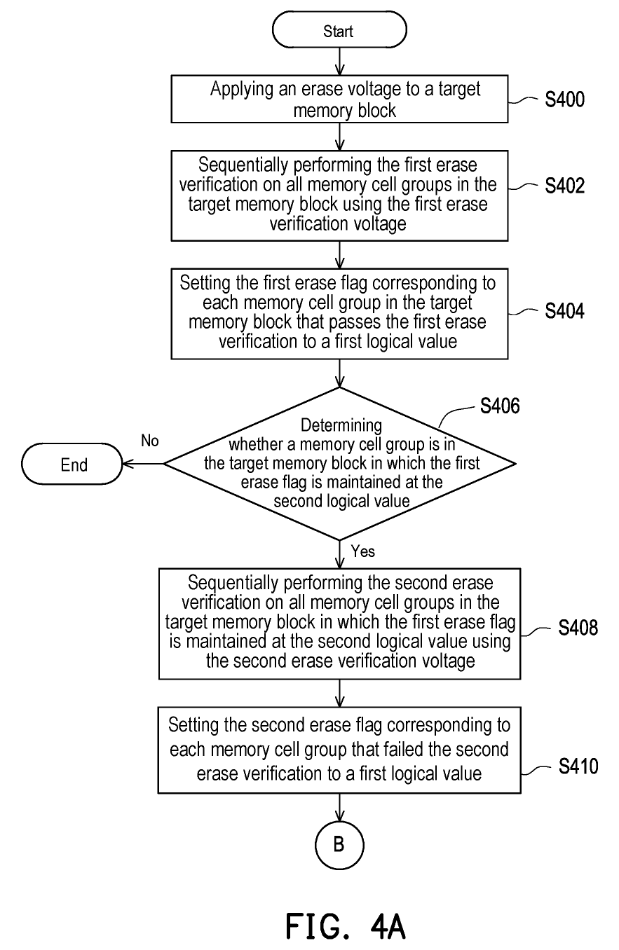

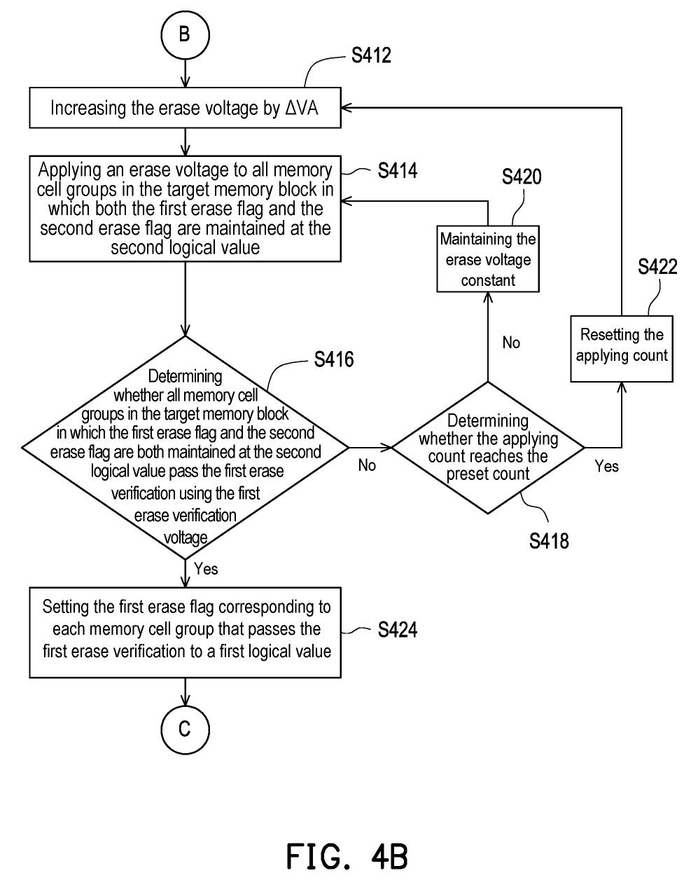

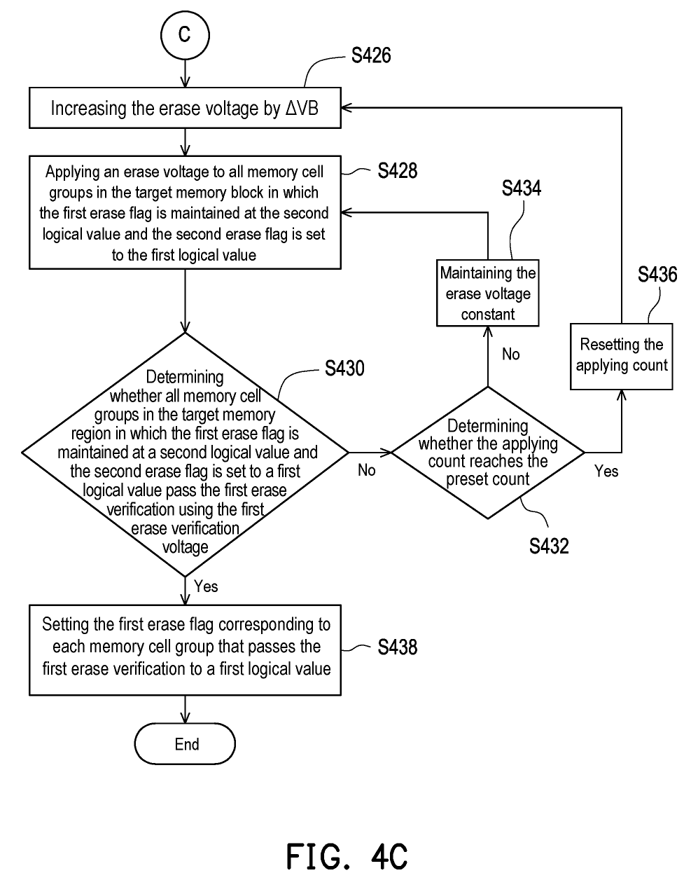

Another embodiment is given below to describe the erasing method of the disclosure in detail. Referring to FIGS. 1, 4A to FIG. 4C at the same time, various steps of the erasing method according to the embodiment of the disclosure are described below with various elements in the flash memory apparatus 100. In this embodiment, the same or similar parts as those in the previous embodiment are not repeated herein. First, in step S400, the control circuit 130 applies the erase voltage Vers to the target memory block 112T. Next, in step S402, the control circuit 130 sequentially performs the first erase verification on all memory cell groups 114 in the target memory block 112T using the first erase verification voltage EV0 to obtain all memory cell groups 114 in the current target memory block 112T that may pass the first erase verification.

Next, in step S404, the control circuit 130 sets the erase flag F1 corresponding to each memory cell group 114 in the target memory block 112T that passes the first erase verification to a first logical value. Next, in step S406, the control circuit 130 determines whether a memory cell group 114 is in the target memory block 112T in which the erase flag F1 is maintained at the second logical value. If not, it means that all memory cell groups 114 in the target memory block 112T have passed the first erase verification. At this time, the control circuit 130 will end the erasing method of this embodiment.

If a memory cell group 114 is in the target memory block 112T in which the erase flag F1 is maintained at the second logical value, then in step S408, the control circuit 130 sequentially performs the second erase verification on all memory cell groups 114 in the target memory block 112T in which the erase flag F1 is maintained at the second logical value using the second erase verification voltage EV1 to obtain all memory cell groups 114 in the current target memory block 112T that may pass the second erase verification.

Next, in step S410, the control circuit 130 sets the erase flag F2 corresponding to each memory cell group 114 that failed the second erase verification to a first logical value, and then proceeds to step S412 of FIG. 4B via node B.

In step S412, the control circuit 130 increases the erase voltage Vers by the first increase amount ΔVA. Next, in step S414, the control circuit 130 only applies the erase voltage Vers to all memory cell groups 114 in the target memory block 112T in which both the erase flag F1 and the erase flag F2 are maintained at the second logical value. Next, in step S416, the control circuit 130 determines whether all memory cell groups 114 in the target memory block 112T in which the erase flag F1 and the erase flag F2 are both maintained at the second logical value pass the first erase verification using the first erase verification voltage EV0. If not, in step S418, the control circuit 130 determines whether the applying count of the erase voltage Vers reaches a preset count. When the applying count of the erase voltage Vers does not reach the preset count, in step S420, the control circuit 130 maintains the erase voltage Vers constant, and then returns to step S414 to continue applying the erase voltage Vers to all memory cell groups 114 in the target memory block 112T in which the erase flag F1 and the erase flag F2 are both maintained at the second logical value. Thereby, the control circuit 130 may repeatedly apply the erase voltage Vers to all memory cell groups 114 in the target memory block 112T in which the erase flag F1 and the erase flag F2 are both maintained at the second logical value until all memory cell groups 114 in the target memory block 112T in which the erase flag F1 and the erase flag F2 are both maintained at the second logical value pass the first erase verification.

Whenever the cumulative applying count of the erase voltage Vers reaches the preset count (Yes in step S418), the control circuit 130 resets the applying count in step S422, then returns to step S412 to increase the erase voltage Vers by the first increase amount ΔVA, and continues to apply the currently adjusted erase voltage Vers to all memory cell groups 114 in the target memory block 112T in which the erase flag F1 and the erase flag F2 are both maintained at the second logical value in step S414.

If all memory cell groups 114 in the target memory block 112T in which the erase flag F1 and the erase flag F2 are both maintained at the second logical value pass the first erase verification (Yes in step S416), then in step S424, the control circuit 130 sets the erase flag F1 corresponding to each memory cell group 114 that passes the first erase verification to a first logical value, and then proceeds to step S426 of FIG. 4C via node C.

In step S426, the control circuit 130 increases the erase voltage Vers by the second increase amount ΔVB. Next, in step S428, the control circuit 130 only applies the erase voltage Vers to all memory cell groups 114 in the target memory block 112T in which the erase flag F1 is maintained at the second logical value and the erase flag F2 is set to the first logical value. Next, in step S430, the control circuit 130 determines whether all memory cell groups 114 in the target memory block 112T in which the erase flag F1 is maintained at the second logical value and the erase flag F2 is set to the first logical value pass the first erase verification using the first erase verification voltage EV0. If not, in step S432, the control circuit 130 determines whether the applying count of the erase voltage Vers reaches a preset count. When the applying count of the erase voltage Vers does not reach the preset count, in step S434, the control circuit 130 maintains the erase voltage Vers constant, and then returns to step S428 to continue applying the erase voltage Vers to all memory cell groups 114 in the target memory block 112T in which the erase flag F1 is maintained at the second logical value and the erase flag F2 is set to the first logical value. Thereby, the control circuit 130 may repeatedly apply the erase voltage Vers to all memory cell groups 114 in the target memory block 112T in which the erase flag F1 is maintained at the second logical value and the erase flag F2 is set to the first logical value until all memory cell groups 114 in the target memory block 112T in which the erase flag F1 is maintained at the second logical value and the erase flag F2 is set to the first logical value pass the first erase verification.

Whenever the cumulative applying count of the erase voltage Vers reaches the preset count (Yes in step S432), the control circuit 130 resets the applying count in step S436, then returns to step S426 to increase the erase voltage Vers by the second increase amount ΔVB, and continues to apply the currently adjusted erase voltage Vers to all memory cell groups 114 in the target memory block 112T in which the erase flag F1 is remained at the second logical value and the erase flag F2 is set to the first logical value in step S428.

If all memory cell groups 114 in the target memory block 112T in which the erase flag F1 is maintained at the second logical value and the erase flag F2 is set to the first logical value pass the first erase verification (Yes in step S430), then in step S438, the control circuit 130 sets the erase flag F1 corresponding to each memory cell group 114 that passes the first erase verification to the first logical value.

In one embodiment, when the total applying count of the erase voltage Vers that the control circuit 130 applies to the target memory block 112T reaches an excessive count, the control circuit 130 may also directly give up (stop) the erase operation on the target memory block 112T to avoid wasting too much erase time.

To sum up, the flash memory apparatus and the erasing method of the disclosure may dynamically adjust the increase amount of the erase voltage and the range of applying the erase voltage according to the type of the memory cell group that has not yet passed the erase verification. In this way, not only may the applying count of the erase voltage and the erase time spent in the erase operation be reduced, but memory cell groups classified into normal groups may also be prevented from continuing to generate leakage current, thus improving the overall efficiency of the erase operation.

What is claimed is:

1. An erasing method of a flash memory apparatus, the flash memory apparatus comprising a plurality of memory blocks, each of the memory blocks being divided into a plurality of memory cell groups, the erasing method comprising:
applying an erase voltage to a target memory block among the memory blocks;
performing a first erase verification on the target memory block using a first erase verification voltage;
performing a second erase verification on the target memory block using a second erase verification voltage higher than the first erase verification voltage in a case that the memory cell group failing the first erase verification is in the target memory block; and
setting a first erase flag and a second erase flag corresponding to each of the memory cell groups in the target memory block according to verification results of the first erase verification and the second erase verification to classify each of the memory cell groups and accordingly adjust increase amount of the erase voltage.

2. The erasing method according to claim 1, wherein performing the first erase verification on the target memory block using the first erase verification voltage comprises:
determining whether a selected memory cell group in the target memory block passes the first erase verification using the first erase verification voltage;
determining whether the selected memory cell group is the last memory cell group in the target memory block when the selected memory cell group passes the first erase verification;
if yes, determining that the target memory block passes the first erase verification; and
if not, selecting next memory cell group in the target memory block as the selected memory cell group to perform the first erase verification.

3. The erasing method according to claim 2, wherein determining whether the selected memory cell group in the target memory block passes the first erase verification using the first erase verification voltage comprises:
determining whether a plurality of memory cells addressed with an access address in the selected memory cell group pass the first erase verification using the first erase verification voltage;
determining whether a current access address corresponds to a last address of the selected memory cell group when the addressed memory cells pass the first erase verification;
if yes, determining that the selected memory cell group passes the first erase verification; and
if not, incrementing the access address to address a plurality of consecutive memory cells in the selected memory cell group to perform the first erase verification.

4. The erasing method according to claim 1, wherein performing the second erase verification on the target memory block using the second erase verification voltage higher than the first erase verification voltage in the case that the memory cell group failing the first erase verification is in the target memory block comprises:
repeatedly applying the erase voltage to the target memory block until all of the memory cell groups in the target memory block pass the first erase verification in a case that the memory cell group that failed the first erase verification is in the target memory block;
accumulating an applying count of the erase voltage; and
resetting the applying count and sequentially performing the second erase verification on all of the memory cell groups in the target memory block using the second erase verification voltage whenever the applying count reaches a preset count,
wherein setting the first erase flag and the second erase flag corresponding to each of the memory cell groups in the target memory block according to the verification results of the first erase verification and the second erase verification comprises:
setting the first erase flag corresponding to each of the memory cell groups that pass the second erase verification to a first logical value, setting the second erase flag corresponding to each of the memory cell groups that failed the second erase verification to the first logical value.

5. The erasing method according to claim 4, wherein classifying each of the memory cell groups comprises:
classifying the memory cell group in which the first erase flag is set to the first logical value as a normal group; and
classifying the memory cell group in which the second erase flag is set to the first logical value as a slow group.

6. The erasing method according to claim 4, wherein accordingly adjusting the increase amount of the erase voltage comprises:
determining whether all of the memory cell groups in the target memory block in which the first erase flag is set to the first logical value pass the first erase verification;
if not, increasing the erase voltage by a first increase amount and continuing to apply the erase voltage to the target memory block; and
if yes, increasing the erase voltage by a second increase amount greater than the first increase amount, and applying the erase voltage to all of the memory cell groups in the target memory block in which the second erase flag is set to the first logical value.

7. The erasing method according to claim 6, wherein after applying the erase voltage to all of the memory cell groups in the target memory block in which the second erase flag is set to the first logical value, the erasing method further comprises:
determining whether all of the memory cell groups in the target memory block in which the second erase flag is set to the first logical value pass the first erase verification using the first erase verification voltage;
if not, repeatedly applying the erase voltage to all of the memory cell groups in the target memory block in which the second erase flag is set to the first logical value until all of the memory cell groups in the target memory block in which the second erase flag is set to the first logical value pass the first erase verification; and
resetting the applying count, and increasing the erase voltage by the second increase amount whenever the applying count of the erase voltage reaches the preset count.

8. The erasing method according to claim 1, wherein performing the second erase verification on the target memory block using the second erase verification voltage higher than the first erase verification voltage in the case that the memory cell group failing the first erase verification is in the target memory block comprises:
setting the first erase flag corresponding to each of the memory cell groups in the target memory block that passes the first erase verification to a first logical value;
determining whether the memory cell group is in the target memory block in which the first erase flag is maintained at a second logical value; and
if yes, sequentially performing the second erase verification on all of the memory cell groups in the target memory block in which the first erase flag is maintained at the second logical value using the second erase verification voltage.

9. The erasing method according to claim 8, wherein setting the first erase flag and the second erase flag corresponding to each of the memory cell groups in the target memory block according to the verification results of the first erase verification and the second erase verification comprises:
setting the second erase flag corresponding to each of the memory cell groups that failed the second erase verification to the first logical value,
wherein, accordingly adjusting the increase amount of the erase voltage comprises:
increasing the erase voltage by a first increase amount;
applying the erase voltage to all of the memory cell groups in the target memory block in which the first erase flag and the second erase flag are both maintained at the second logical value;
determining whether all of the memory cell groups in the target memory block in which the first erase flag and the second erase flag are both maintained at the second logical value pass the first erase verification using the first erase verification voltage;
if yes, setting the first erase flag corresponding to each of the memory cell groups that passes the first erase verification to the first logical value;
if not, repeatedly applying the erase voltage to all of the memory cell groups in the target memory block in which the first erase flag and the second erase flag are both remained at the second logical value until all of the memory cell groups in the target memory block in which the first erase flag and the second erase flag are both remained at the second logical value pass the first erase verification; and
resetting an applying count, and increasing the erase voltage by the first increase amount whenever the applying count of the erase voltage reaches a preset count.

10. The erasing method according to claim 9, wherein after setting the first erase flag corresponding to each of the memory cell groups that passes the first erase verification to the first logical value, the erasing method further comprises:
increasing the erase voltage by a second increase amount greater than the first increase amount;
applying the erase voltage to all of the memory cell groups in the target memory block in which the first erase flag is maintained at the second logical value and the second erase flag is set to the first logical value;
determining whether the memory cell groups in the target memory block in which the first erase flag is maintained at the second logical value and the second erase flag is set to the first logical value pass the first erase verification using the first erase verify voltage;
if yes, setting the first erase flag corresponding to each of the memory cell groups that passes the first erase verification to the first logical value;
if not, repeatedly applying the erase voltage to all of the memory cell groups in the target memory block in which the first erase flag is maintained at the second logical value and the second erase flag is set to the first logical value until all of the memory cell groups in the target memory block in which the first erase flag and the second erase flag are both maintained at the second logical value pass the first erase verification; and
resetting the applying count, and increasing the erase voltage by the second increase amount whenever the applying count of the erase voltage reaches the preset count.

11. A flash memory apparatus, comprising:
a memory array, having a plurality of memory blocks, each of the memory blocks being divided into a plurality of memory cell groups;
a flag register, configured to store a first erase flag and a second erase flag corresponding to each of the memory cell groups; and
a control circuit, coupled to the memory array and the flag register, and configured to perform an erase operation on a target memory block among the memory blocks,
wherein, the control circuit applies an erase voltage to the target memory block, and performs a first erase verification on the target memory block using a first erase verification voltage,
the control circuit performs a second erase verification on the target memory block in a case that the memory cell group failing the first erase verification is in the target memory block using a second erase verification voltage higher than the first erase verification voltage, and sets the first erase flag and the second erase flag corresponding to each of the memory cell groups in the target memory block according to verification results of the first erase verification and the second erase verification to classify each of the memory cell groups and accordingly adjust increase amount of the erase voltage.

12. The flash memory apparatus according to claim 11, wherein the control circuit determines whether a selected memory cell group in the target memory block passes the first erase verification using the first erase verification voltage,
the control circuit determines whether the selected memory cell group is the last memory cell group in the target memory block when the selected memory cell group passes the first erase verification, if yes, the control circuit determines that the target memory block passes the first erase verification, if not, the control circuit selects next memory cell group in the target memory block as the selected memory cell group to perform the first erase verification.

13. The flash memory apparatus according to claim 12, wherein the control circuit determines whether a plurality of memory cells addressed with an access address in the selected memory cell group pass the first erase verification using the first erase verification voltage,
the control circuit determines whether a current access address corresponds to a last address of the selected memory cell group when the addressed memory cells pass the first erase verification, if yes, the control circuit determines that the selected memory cell group passes the first erase verification, if not, the control circuit increments the access address to address a plurality of consecutive memory cells in the selected memory cell group to perform the first erase verification.

14. The flash memory apparatus according to claim 11, wherein the control circuit repeatedly applies the erase voltage to the target memory block until all of the memory cell groups in the target memory block pass the first erase verification in a case that the memory cell group that failed the first erase verification is in the target memory block;
the control circuit accumulates an applying count of the erase voltage, the control circuit resets the applying count and sequentially performs the second erase verification on all of the memory cell groups in the target memory block using the second erase verification voltage whenever the applying count reaches a preset count,
the control circuit sets the first erase flag corresponding to each of the memory cell groups that pass the second erase verification to a first logical value, and sets the second erase flag corresponding to each of the memory cell groups that failed the second erase verification to the first logical value.

15. The flash memory apparatus according to claim 14, wherein the control circuit classifies the memory cell group in which the first erase flag is set to the first logical value as a normal group and classifies the memory cell group in which the second erase flag is set to the first logical value as a slow group.

16. The flash memory apparatus according to claim 14, wherein the control circuit determines whether all of the memory cell groups in the target memory block in which the first erase flag is set to the first logical value pass the first erase verification, if not, the control circuit increases the erase voltage by a first increase amount and continues to apply the erase voltage to the target memory block, if yes, the control circuit increases the erase voltage by a second increase amount greater than the first increase amount and applies the erase voltage to all of the memory cell groups in the target memory block in which the second erase flag is set to the first logical value.

17. The flash memory apparatus according to claim 16, wherein the control circuit determines whether all of the memory cell groups in the target memory block in which the second erase flag is set to the first logical value pass the first erase verification using the first erase verification voltage, if not, the control circuit repeatedly applies the erase voltage to all of the memory cell groups in the target memory block in which the second erase flag is set to the first logical value until all of the memory cell groups in the target memory block in which the second erase flag is set to the first logical value pass the first erase verification, the control circuit resets the applying count, and increases the erase voltage by the second increase amount whenever the applying count of the erase voltage reaches the preset count.

18. The flash memory apparatus according to claim 11, wherein the control circuit sets the first erase flag corresponding to each of the memory cell groups in the target memory block that passes the first erase verification to a first logical value,
the control circuit determines whether the memory cell group is in the target memory block in which the first erase flag is maintained at a second logical value, if yes, the control circuit sequentially performs the second erase verification on all of the memory cell groups in the target memory block in which the first erase flag is maintained at the second logical value using the second erase verification voltage.

19. The flash memory apparatus according to claim 18, wherein the control circuit sets the second erase flag corresponding to each of the memory cell groups that failed the second erase verification to the first logical value,
the control circuit increases the erase voltage by a first increase amount and applies the erase voltage to all of the memory cell groups in the target memory block in which the first erase flag and the second erase flag are both maintained at the second logical value,
the control circuit determines whether all of the memory cell groups in the target memory block in which the first erase flag and the second erase flag are both maintained at the second logical value pass the first erase verification using the first erase verification voltage, if yes, the control circuit sets the first erase flag corresponding to each of the memory cell groups that passes the first erase verification to the first logical value, if not, the control circuit repeatedly applies the erase voltage to all of the memory cell groups in the target memory block in which the first erase flag and the second erase flag are both remained at the second logical value until all of the memory cell groups in the target memory block in which the first erase flag and the second erase flag are both remained at the second logical value pass the first erase verification,
the control circuit resets an applying count and increases the erase voltage by the first increase amount whenever the applying count of the erase voltage reaches a preset count.

20. The flash memory apparatus according to claim 19, wherein the control circuit increases the erase voltage by a second increase amount greater than the first increase amount, and applies the erase voltage to all of the memory cell groups in the target memory block in which the first erase flag is maintained at the second logical value and the second erase flag is set to the first logical value,
the control circuit determines whether the memory cell groups in the target memory block in which the first erase flag is maintained at the second logical value and the second erase flag is set to the first logical value pass the first erase verification using the first erase verify voltage, if yes, the control circuit sets the first erase flag corresponding to each of the memory cell groups that passes the first erase verification to the first logical value, if not, the control circuit repeatedly applies the erase voltage to all of the memory cell groups in the target memory block in which the first erase flag is maintained at the second logical value and the second erase flag is set to the first logical value until all of the memory cell groups in the target memory block in which the first erase flag and the second erase flag are both maintained at the second logical value pass the first erase verification,
the control circuit resets the applying count and increases the erase voltage by the second increase amount whenever the applying count of the erase voltage reaches the preset count.
